(19) United States
(12) Patent Application Publication
(10) Pub. No.: US 2026/0299052 A1
(43) Pub. Date: Oct. 1, 2026

(54) BLOCH-SIMULATOR-BASED JOINT RECONSTRUCTION AND FIELD INHOMOGENEITY ESTIMATION WITH PLUG-AND-PLAY DENOISING DIFFUSION MODEL

(71) Applicant: Siemens Healthineers AG, Forchheim (DE)

(72) Inventors: Yahang Li, Plainsboro, NJ (US); Mahmoud Mostapha, Princeton, NJ (US); Radu Miron, Iasi (RO); Boris Mailhe, Plainsboro, NJ (US); Nirmal Janardhanan, Alpharetta, GA (US); Shihan Qiu, Plainsboro, NJ (US); Thorsten Feiweier, Poxdorf (DE); Marcel Dominik Nickel, Herzogenaurach (DE); Stephan Kannengießer, Wuppertal (DE); Rainer Schneider, Höchstadt (DE); David Grodzki, Erlangen (DE); Daniel Niederlöhner, Erlangen (DE); Cornelius Eichner, Fürth (DE); Wei Liu, Erlangen (DE); Omar Darwish, London (GB); Bryan Clifford, Belmont, MA (US); Tobias Würfl, Erlangen (DE); Till Hülnhagen, Erlangen (DE); Dieter Ritter, Fürth (DE); Michael Köhler, Nürnberg (DE); Mariappan S. Nadar, Plainsboro, NJ (US)

(21) Appl. No.: 19/089,126

(22) Filed: Mar. 25, 2025

(51) Int. Cl. G01R 33/00; G01R 33/56; G01R 33/565; G01R 33/58

(52) U.S. Cl. CPC G01R 33/0064; G01R 33/5608; G01R 33/565; G01R 33/583

(57) ABSTRACT

Systems and methods for Bloch-simulator-based joint reconstruction and field inhomogeneity estimation within a plug-and-play diffusion framework, where field inhomogeneity is modeled using a fully differentiable Bloch simulation.

### FIELD

This disclosure relates to medical imaging.

### BACKGROUND

Magnetic resonance imaging, or MRI, is a noninvasive medical imaging modality that can generate detailed images of almost every internal structure in the human body, including, for example organs, bones, muscles, and blood vessels. MRI reconstruction converts raw MRI data from an MRI scan into interpretable medical images. For an imaging procedure, MRI scanners acquire spatial frequency data (k-space) through the application of magnetic gradients and radiofrequency pulses. Image reconstruction mathematically transforms this frequency-domain data into spatial-domain images, typically via inverse Fourier transforms. Reconstruction methods (mostly in the form of iterative algorithms) may use advanced signal processing (e.g., compressed sensing) and machine learning with the help of differentiable physics models to correct artifacts, reduce noise, enhance resolution, etc. The goal of image reconstruction is accurate, clinically informative images that precisely represent anatomical structures, tissue contrasts, and functional information, thereby aiding in diagnosis, treatment planning, and medical research.

General Fourier transform-based MRI reconstruction relies on the assumption of uniformity in the main B0 field and linearity in the field gradients of the MRI scanner during an imaging procedure. However, these assumptions of homogeneity may be violated by several physical factors, including system imperfections, design restrictions, and material or tissue susceptibility differences. As a result, severe imaging artifacts, such as geometric distortions, blurring, and ghosting, may occur. Conventional distortion correction methods addressing field inhomogeneity typically require additional measurements to capture B0 variations and may have suboptimal performance when dealing with insufficient signal-to-noise ratio (SNR) or inaccurate registration between the additional scan and the original measurements.

Recently, with advancements in machine learning, neural-network-based methods have been proposed to correct B0 inhomogeneity-induced distortions from a single or paired image. However, errors in B0 estimation can persist in low-SNR regions. Consequently, other approaches have been developed for joint reconstruction of B0 inhomogeneity and the image using conventional model-based, alternating optimization schemes. Although these approaches show promise, the priors used in the alternating subproblems are often limited to either smoothness constraints or a conventional learned unrolling framework.

### SUMMARY

By way of introduction, the preferred embodiments described below include methods, systems, instructions, and/or computer readable media for Bloch-simulator-based joint reconstruction and field inhomogeneity estimation with a plug-and-play denoising diffusion model.

In a first aspect, a method for Bloch-simulator-based joint reconstruction and field inhomogeneity estimation is provided the method comprising: performing a patient scan using a MR protocol, the patient scan generating raw MR data; inputting the raw MR data and the MR protocol into a MR simulator configured to implement a joint reconstruction framework, wherein the joint reconstruction framework alternates optimizations of a field inhomogeneity map and tissue parameters using a plug-and-play diffusion framework; and outputting, by the simulator-based-reconstruction framework, one or more tissue parameter maps.

In a second aspect, a system for Bloch-simulator-based joint reconstruction and field inhomogeneity estimation is provided, the system comprising: an magnetic resonance (MR) scanner configured to scan a patient using a MR protocol, the scan generating MR data; and a MR simulator, the MR simulator configured to implement a joint reconstruction framework, wherein the joint reconstruction framework alternates optimizations of a field inhomogeneity map and tissue parameters using a plug-and-play diffusion framework, the simulator-based reconstruction framework configured to output, when input the MR data and MR protocol, one or more tissue parameter maps.

In a third aspect, a non-transitory computer implemented storage medium is provided, including machine-readable instructions stored therein for Bloch-simulator-based joint reconstruction and field inhomogeneity estimation, the instructions when executed by at least one processor, cause the processor to: acquire MR data of a patient acquired in an imaging procedure using a MR protocol; input the raw MR data and the MR protocol into a MR simulator configured to compute tissue parameters and the field inhomogeneity using a joint reconstruction framework, wherein the joint reconstruction framework alternates optimizations of a field inhomogeneity map and tissue parameters using a plug-and-play diffusion framework; and output one or more tissue parameter maps for the imaging procedure.

Any one or more of the aspects described above may be used alone or in combination. These and other aspects, features and advantages will become apparent from the following detailed description of preferred embodiments, which is to be read in connection with the accompanying drawings. The present invention is defined by the following claims, and nothing in this section should be taken as a limitation on those claims. Further aspects and advantages of the invention are discussed below in conjunction with the preferred embodiments and may be later claimed independently or in combination.

### BRIEF DESCRIPTION OF THE DRAWINGS

The components and the figures are not necessarily to scale, emphasis instead being placed upon illustrating the principles of the embodiments. Moreover, in the figures, like reference numerals designate corresponding parts throughout the different views.

FIG. 1 depicts an example system for magnetic resonance imaging.

FIG. 2 depicts an example workflow for Bloch-simulator-based joint reconstruction and field inhomogeneity estimation according to an embodiment.

FIG. 3 depicts an example diffusion process.

FIG. 4 depicts an example method for Bloch-simulator-based joint reconstruction and field inhomogeneity estimation according to an embodiment.

FIG. 5 depicts an example system for Bloch-simulator-based joint reconstruction and field inhomogeneity estimation according to an embodiment.

FIG. 6 depicts an example U-net architecture.

FIG. 7 depicts an example artificial neural network.

FIG. 8 depicts an example convolutional neural network.

### DETAILED DESCRIPTION

Embodiments described herein provide systems and methods for a Bloch-simulator-based joint reconstruction within a plug-and-play diffusion framework, where the full imaging process (with all the non-ideal behaviors, e.g., field inhomogeneities) is modeled using a fully differentiable Bloch simulation. This approach provides a more accurate representation of the underlying physics than conventional reconstructions and enables simultaneous accommodation of various physical effects, such as gradient nonlinearity and eddy currents, in addition to static B0 inhomogeneity. The Bloch-simulator-based joint reconstruction also directly reconstruct tissue parameter maps from the data, where diffusion priors are adapted within a plug-and-play framework, offering enhanced reconstruction capabilities (e.g., high-SNR, high-undersampled reconstruction).

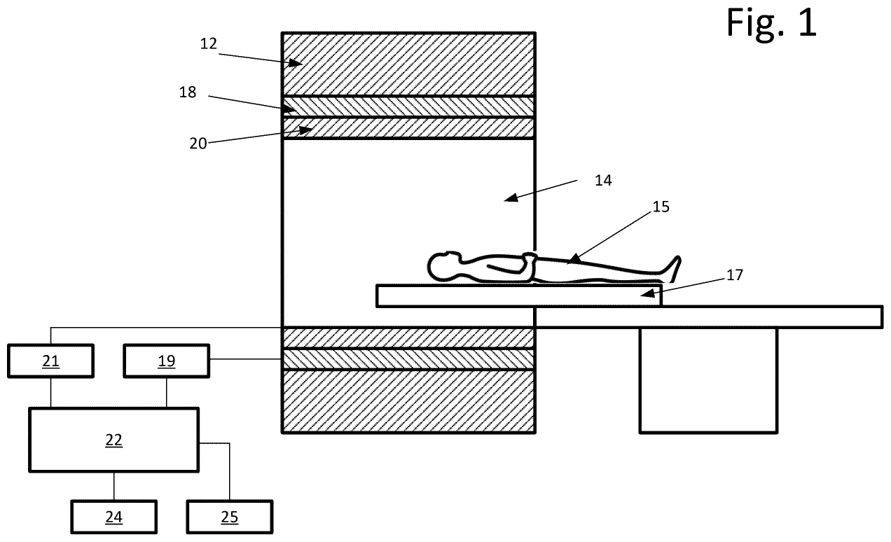

FIG. 1 depicts an example magnetic resonance apparatus 10. The magnetic resonance apparatus 10 includes a magnetic unit 11 that includes a main magnet 12 for the generation of a main magnetic field 13. In addition, the magnetic resonance apparatus 10 includes a patient receiving area 14 for receiving a patient 15. The patient receiving area 14 may be cylindrical in design and cylindrically surrounded by the magnetic unit 11 in a circumferential direction. Different designs of the patient receiving area 14 may be used. The patient 15 may be pushed into the patient receiving area 14 by a patient positioning device of the magnetic resonance apparatus 10. The patient positioning device includes a patient table 17 for this purpose that is configured to be movable within the patient receiving area 14.

The magnetic unit 11 also includes a gradient coil unit 18 for the generation of gradient pulses that are used for location coding during imaging. The gradient coil unit 18 is controlled by a gradient control unit 19 of the magnetic resonance apparatus 10. The magnetic unit 11 also includes a radio frequency antenna unit 20, that may be configured as a body coil permanently integrated into the magnetic resonance apparatus 10. The radio frequency antenna unit 20 is controlled by a radio frequency antenna control unit 21 of the magnetic resonance apparatus 10 and emits RF transmission pulses into an examination area during a magnetic resonance measurement, that is essentially formed by a patient receiving area 14 of the magnetic resonance apparatus 10. As a result, atomic nuclei which are present in the main magnet field generated by the main magnet 12 are excited. Magnetic resonance signals are generated by relaxation of the excited atomic nuclei. The radio frequency antenna unit 20 is configured to receive magnetic resonance signals.

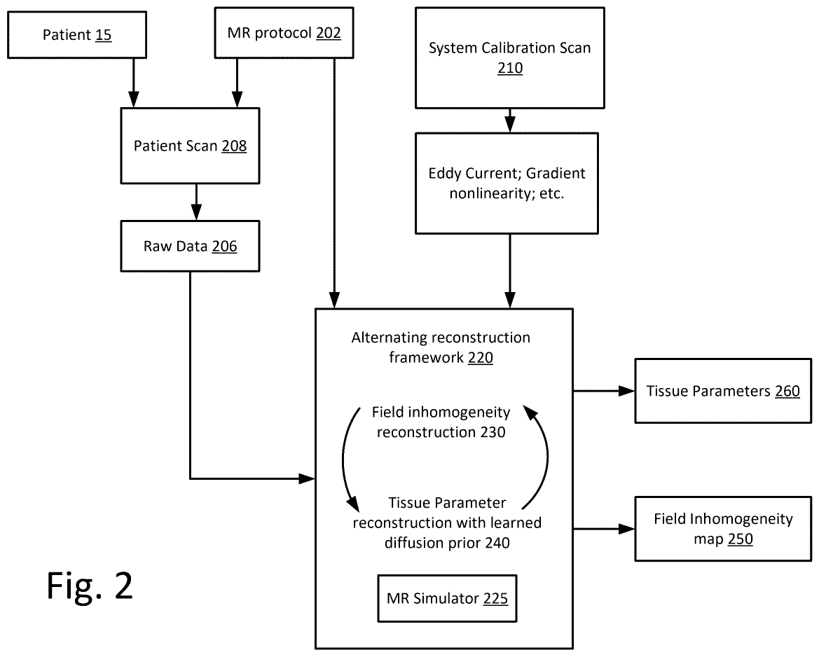

The magnetic resonance apparatus 10 includes a system control unit 22 for controlling the main magnet 12, the gradient control unit 19 and for controlling the radio frequency antenna control unit 21. The system control unit 22 controls the magnetic resonance apparatus 10, such as, for example, performing a predetermined imaging magnetic resonance measurement. The system control unit 22 may be configured to execute a computer-implemented method for generating magnetic resonance images, as shown in FIGS. 2 and/or 4.

In addition, the system control unit 22 includes an evaluation unit 60 not shown here in more detail for evaluating the magnetic resonance signals that are recorded during the magnetic resonance examination. The evaluation 60 includes a processor 62, memory 64, and interface 66. Furthermore, the magnetic resonance apparatus 10 may also include a user interface for a medical operator that is connected to the system control unit 22. Control information such as, for example imaging parameters, as well as reconstructed magnetic resonance images may be displayed on a display unit 24, for example on at least one monitor. Furthermore, the user interface has an input unit 25 by which information and/or parameters may be entered by the medical operator during a measurement process.

MRI raw data acquisition involves placing a patient 15 in a strong magnetic field and applying controlled radiofrequency pulses and gradient magnetic fields. These gradients encode spatial information into the MRI signal, collected as frequency-domain data, known as k-space. Reconstruction transforms k-space data into anatomical images. In MRI, the B0 field refers to the main, static magnetic field produced by the scanner, which is a strong, constant magnetic field that aligns the protons in the patient's tissues, allowing for the detection of their signal during an MRI scan. The term B0 field inhomogeneity refers to unevenness or variations in the strength of the main static magnetic field (B0) across the imaging volume, which can lead to image distortions, signal loss, and other artifacts in the final image due to different tissue types or air cavities having slightly different magnetic susceptibilities when placed within the scanner's magnetic field. MRI imaging may require distortion correction because these magnetic field inhomogeneities (and gradient imperfections) cause geometric inaccuracies, misrepresenting anatomical positions and tissue structures. Uncorrected distortions compromise diagnostic accuracy, reduce reliability of quantitative measurements, impair multimodal image alignment, and negatively affect surgical planning, clinical assessments, and advanced medical imaging analyses.

Various MRI distortion correction methods have been used to address signal intensity and geometric inaccuracies due to magnetic field inhomogeneities. Techniques include field map-based methods, where spatial field maps are generated to correct susceptibility-induced distortions; TopUp, which uses paired images with reversed phase-encoding directions to estimate displacement fields; and gradient non-linearity correction, applying scanner-specific calibration maps among other techniques. Conventional distortion correction methods, such as TopUp have been used to address signal pile-up and stretching distortions, for example in echo planar imaging (EPI), through a specially designed paired acquisition strategy, i.e., measurements with opposite phase encoding gradient directions, followed by a registration-based correction that estimate a common B0 field, ensuring identical corrected images from the paired acquisitions. More specifically, TopUp leverages pairs of images acquired with opposite phase-encoding directions (e.g., anterior-posterior and posterior-anterior). Due to the physics of MRI acquisition, reversing the phase-encoding direction reverses the distortion pattern, regions compressed in one direction become expanded in the opposite direction. By comparing these pairs of oppositely distorted images, TopUp estimates a common displacement (field distortion) map between the paired images.

An alternative field map-based approach tries to directly measure the B0 variation from a dedicated measurement (e.g., gradient echo sequences (GRE) with different echo times), where the measured B0 map may be built into an imaging model as a reconstruction problem. While effective, this technique relies heavily on the SNR level of the GRE images and quality of the registration process between the GRE and the measurements of interest, which may not always be robust under challenging conditions, leading to suboptimal correction outcomes. Moreover, considerable time may be required to measure a B0 map with sufficient precision, thus extending the duration of the examination procedure.

With the recent advances in machine learning, neural network-based techniques have emerged as powerful alternatives. These methods either directly perform the distortion correction on the distorted images or provides an estimation of a B0 map, which is subsequently incorporated into model-based reconstructions. While these approaches offer potential improvements in speed and flexibility, the issue of accurate B0/distortion estimation in regions with insufficient SNR remains a challenge under certain (for example extreme) imaging conditions. To better resolve the residual B0 estimation error, several model-based joint reconstruction methods have been proposed within an alternating optimization scheme that includes two regularized reconstructions with one focusing on an accurate estimation of the B0 map and the other on the distortion correction and denoising performance. The prior (regularizer) used in those methods are currently limited to either conventional spatial smooth constraints or build into a learned un-rolling pipeline.

Embodiments described herein solve for the field-inhomogeneity-induced artifact through Bloch-simulator-based joint reconstruction framework by 1) alternating optimizations of the field-inhomogeneity and the tissue parameters modeled by a physics-driven Bloch simulator and 2) incorporating a diffusion prior to effectively solve the tissue parameter estimation subproblem. This approach offers a robust correction pipeline capable of working across various MRI sequence types. The joint reconstruction framework inherently provides better resilience to any errors in the initial B0 estimation (if any), allowing for more accurate corrections and improved image quality. In addition, the Bloch simulator offers a more accurate representation of the underlying physics of MRI, allowing it to account for a range of physical effects, including gradient nonlinearity and eddy currents, in addition to static B0 inhomogeneity. The simulator-based model provides the capability of directly reconstructing tissue parameter maps (or high-quality images) from the data with sufficient measurement (e.g., multi-echo (TE) acquisitions). Finally, the plug-and-play diffusion framework used for the tissue parameter reconstruction subproblem further enhances the reconstruction performance (e.g., high-SNR and high-undersampled reconstruction).

FIG. 2 depicts an example workflow for solving for the field-inhomogeneity-induced artifact through Bloch-simulator-based joint reconstruction framework by alternating optimizations of the field-inhomogeneity and the tissue parameter. In FIG. 2, MR raw data 206 is acquired using a patient scan 208 of a patient 15 with the provided protocol 202. In an embodiment, system behaviors derived from a calibration scan 210, e.g., eddy current, gradient nonlinearity, etc. may also be provided to the MR simulator 225. The MR raw data 206 is input into the MR simulator 225 which outputs a field inhomogeneity map 250 and/or one or more tissue parameters 260 alone. The differentiability of the MR simulator 225 allows for an alternating reconstruction 230, 240 of the field inhomogeneity reconstruction 230 and tissue parameter reconstruction 240. For enhanced reconstruction performance of tissue parameters, a diffusion-model-based plug-and-play framework is used.

Embodiments provide joint reconstruction addressing field inhomogeneity and tissue parameter estimation. The joint reconstruction simultaneously corrects for spatially varying magnetic field (B0) distortions and estimates intrinsic tissue parameters such as T₁, T₂, proton density (PD), or diffusion properties (e.g., apparent diffusion coefficient) within a unified optimization framework. The integrated method contrasts with traditional sequential approaches, which handle field correction and parameter estimation as separate, often independently optimized steps. Specifically, the proposed joint optimization scheme includes two alternating minimization subproblems that solved through efficient iterative algorithms. In a field estimation subproblem, given the current estimate of tissue parameters, the field map is updated by solving a least-square problem that aims to find the optimal field map that best match distortion pattern from the measured data. With the differentiability of Bloch-simulator, this subproblem can be effectively solved through general gradient descend algorithms. In the tissue parameter estimation step, with the updated field map, tissue parameters are optimized to provide best contrast alignment with the measured data. This subproblem is solved within a plug-and-play framework using a learned diffusion prior.

In an embodiment, the MR simulator 225 uses a fully differentiable Bloch simulation. The fully differentiable Bloch simulator 225 is a computational model of MR signal formation that computes gradients (derivatives) of simulated MRI signals with respect to the input parameters. This includes parameters related to tissue properties (such as T₁, T₂, proton density), pulse-sequence settings (flip angles, echo/repetition times, gradient shapes), and magnetic field inhomogeneities (B₀, B₁ fields). In an example operation, one or more of tissue parameters, pulse-sequence parameters, and field parameters are input into the MR simulator 225. In a forward pass, the simulator 225 computes magnetization trajectories using numerical integration or analytic solutions of Bloch equations. The MR simulator 225 generates complex-valued MR signals at specific sampling points. In a backwards pass, the simulator 225 backpropagates through the numerical solver to compute derivatives. Gradients obtained are used for optimization.

In an embodiment, the workflow alternates optimizations of a field inhomogeneity and tissue parameters. The overall reconstruction problem may be formulated as a joint minimization problem over the field inhomogeneity and a set of high-dimensional tissue parameter maps using the following equation:

$${min}_{f , {\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) + {R}_{f} ( f ) , \qquad EQUATION 1$$

where d_{c} is the k-space measurement for the c-th coil. Sim{·} represent the fully differentiable Bloch simulator 225 with input including: Φ sequence parameters retrieved from the measurement protocol, s_{c} the coil sensitivity for the c-th coil,

$${\{ {P}_{i} \}}_{i = 0}^{l}$$

tissue parameter maps with in-total l components (e.g., T1, T2, etc.), and f the field inhomogeneity maps. Note that the MR simulator 225 also allows for the incorporation of various system-dependent field perturbations, such as gradient nonlinearity and eddy currents that may be pre-determined or provided with a system-wise calibration scan.

In equation 1, Rₚ(·) and R_{f}(·) denote two different regularizers for the tissue parameters and field inhomogeneity respectively. Directly solving the problem is challenging, thus an alternating optimization approach is applied to separate the original problem into two subproblems. In an embodiment, the optimization problem for the tissue parameters reconstruction can be written as the following:

Subproblem 1: for a fixed f, the resulting subproblem is defined as:

$${min}_{{\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) .$$

which is treated as a distortion-resolved, SNR-enhancing, undersampled tissue parameter reconstruction problem. One very important aspect of this problem is the choice of Rₚ(·). With the extensive development of machine learning, diffusion-based priors have demonstrated superior performance across various tasks, including MR reconstruction. The above subproblem is solved by adapting a diffusion-model-based plug-and-play framework referred to as DIFFPIR. DIFFPIR provides a diffusion model-based sampling technique for plug-and-play image restoration. Specifically, DIFFPIR employs a Half Quadratic Splitting (HQS)-based diffusion sampling approach that utilizes off the shelf diffusion models as plug-and-play denoising prior and solves the data subproblem in the clean image manifold. In DIFFPIR, the diffusion sampling framework offers a more systematic approach to solve data sub-problems and prior sub-problems in an iterative plug and play manner. Here in this specific implementation, Bloch-simulator-based data term

$$( i . e . , {‖ {d}_{c} - Sim \{ Φ , {s}_{c} , {\{ {P}_{i} \}}_{i = 0}^{l} , f \} ‖}_{F} )$$

is decoupled from the prior term

$$( i . e . , {R}_{P} ( {\{ {P}_{i} \}}_{i = 0}^{l} ) )$$

to leverage the DIFFPIR-like diffusion sampling process. More specifically, by introducing an auxiliary variable, the problem may be split into the following sub-subproblems and be solved iteratively within each of the diffusion-sampling steps with a pre-trained diffusion prior [symbol] (·).

The subproblem 1 may be re-written as the following sub-subproblems (with

$$P = {\{ {P}_{i} \}}_{i = 0}^{l}$$

and fixed f):

$$\begin{matrix}{P}_{0}^{( t )} = {arg min}_{z} \frac{1}{2 {\overline{σ}}_{t}^{2}} {‖ z - {P}_{t} ‖}^{2} + 𝒫 ( z ) \\ {\hat{P}}_{0}^{( t )} = {arg min}_{P} {‖ d - Sim \{ Φ , {s}_{c} , P , f \} ‖}^{2} + {ρ}_{t} ‖ P - {P}_{0}^{t} ‖ \\ {P}_{t - 1} ← {\hat{P}}_{0}^{( t )} .\end{matrix}$$

As illustrated in DIFFPIR, the first sub-subproblem with the prior term (i.e., [symbol] (z)) is a Gaussian denoising problem which can be effective solved by treating the learned score model (or the diffusion prior) as denoiser. In short, at every timestep t, the method initially estimates

$${P}_{0}^{( t )}$$

from Pₜ through denoising, using an off-the-shelf unconditional pre-trained diffusion model (the detailed algorithm can be find in the original DIFFPIR paper). The second sub-subproblem with the data term is a proximal operator that has a closed-form solution that depends on Sim{·} that is fully differentiable. The prior term ensures that the generated sample is from the prior data distribution (here learned by a diffusion model), while the data term refines the image manifold based on the given measurement.

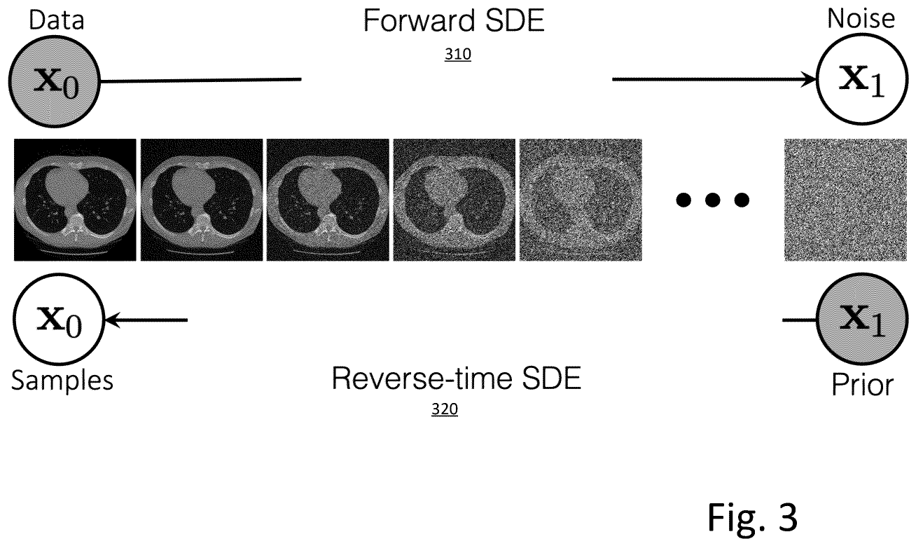

In an embodiment, the workflow integrates pre-trained diffusion models into the HQS framework. This integration allows the generative power of diffusion models to guide the restoration process, effectively capturing complex image structures and details. FIG. 3 depicts an example of a generative diffusion process for image processing including the forward process 310 and the reverse process 320. The goal of the diffusion model is to learn the diffusion process for a given dataset, such that the process can generate new elements that are distributed similarly as the original dataset (i.e., sampling from the learned prior distribution). In the forward process 310 noise is added to the input image over and over again until the image is practically all noise. At each training step, the diffusion model (or the score function) learns how to map a noisy image to their corresponding noise-free version at each of the forward diffusion steps so that in the reverse step 320, the learned diffusion model can be used to recover the data by reversing this noising process. Image reconstruction in MRI is a similar inverse problem but attempts to compute an image from actual scan measurements (i.e., sampling from a posterior as opposed to prior learned by the conventional diffusion framework). Thus, in an embodiment, the diffusion model is a plug-and-play diffusion model with the imaging model (Bloch-simulator) incorporated to enforce the correct posterior during diffusion-sampling phase. In the above equation, the pre-learned prior [symbol] (·) is a critical component of the method that may be challenging to construct due to the limited availability of training data for tissue parameters. Therefore, additional training to fine tune the model may be used such as one shot or few shot training. In an example, the diffusion model may serve directly as the tissue parameter prior in subproblem 1. In another embodiment, a general prior [symbol] (x) may be estimated, where [symbol] (x) represents the distribution of general MR images with varying contrasts, by leveraging large public datasets that provide a broad foundation for learning. Then few-shot learning techniques may be used to adapt the prior conditioned on to the joint tissue parameter tensor P. The tissue parameter estimation is inherently a very high dimensional problem; thus, a sufficient amount of measurements may be necessary (e.g., multi-TE/TR/TIs acquisitions).

Referring back to equation 1, for Subproblem 2: for a fixed P, the subproblem may be solved using:

$${min}_{f} {‖ {d}_{c} - Sim \{ Φ , {s}_{c} , P , f \} ‖}_{F} + {R}_{f} ( f ) ,$$

Here with the full differentiability of the diffusion model

$$( i . e . , \frac{d ( Sim \{ Φ , {s}_{c} , P , f \} )}{df} ) ,$$

this subproblem may be effectively solved with a general gradient descent algorithm. A spatial smoothness constraint can be applied to the field map f, which has been proven effective in various applications (e.g.,

$${R}_{f} ( f ) = {‖ Df ‖}_{2}^{2}$$

where D denotes a weighted finite difference operator)

The method solves for the field-inhomogeneity-induced artifact through Bloch-simulator-based joint reconstruction framework by alternating optimizations of the field-inhomogeneity and the tissue parameters. The iterative approach offers a robust correction pipeline capable of working across various MRI sequence types. The joint reconstruction framework inherently provides better resilience to any errors in the initial B0 estimation (if any), allowing for more accurate corrections and improved image quality. The simulator-based model enables simultaneous, distortion-free reconstruction of tissue parameters, providing enhanced information for potential downstream diagnostic tasks. The diffusion prior employed during tissue parameter reconstruction enhances performance, especially in challenging reconstruction scenarios.

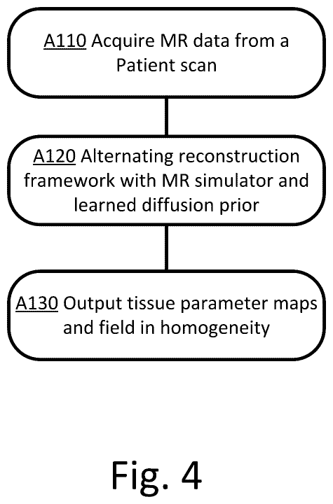

FIG. 4 depicts an example method for field inhomogeneity and/or tissue parameters estimation. The method is performed by the system of FIG. 1 or another system. The method is performed in the order shown or other orders. Additional, different, or fewer acts may be provided.

At act A110, a patient scan is performed using a MR protocol, the patient scan generating raw MR data. The medical imaging data may be acquired using an MRI scanning system such as describe in FIG. 1. Alternatively, the medical imaging data may be provided from another source such as a database or a previous scan.

In an embodiment, additional information about the scanner such as gradient nonlinearity and eddy currents may be acquired using a calibration scan performed at any point prior or after to scanning the patient 15. In an example, a calibration scan may be performed daily, monthly, yearly, etc. The calibration scan is a brief system-behavior analyzation scan run on the machine before or after a patient scan. A specialized phantom object with known dimensions and properties may be scanned to check parameters such as the magnetic field homogeneity, coil tuning, and signal reception across the imaging volume. In an embodiment, a calibration scan may be performed while the patient 15 is in the bore of the MR apparatus 10, which provides up-to-date information, including any deviations introduced by the body.

At act A120, the raw MR data and the MR protocol are input into an alternating reconstruction framework 220 configured with a fully differentiable Bloch simulation and a plug-and-play diffusion algorithm, wherein the joint reconstruction framework 220 alternates optimizations of a field inhomogeneity and tissue parameters. The MR simulator in the reconstruction framework 220 utilizes Bloch equations to simulate the behavior of nuclear magnetization within a magnetic field. The MR simulator in the reconstruction framework 220 is configured to simulate different MRI pulse sequences and compute how they affect the signal generated from a tissue sample. Given the input protocol and MR raw data, the reconstruction framework 220 is configured to output data (maps) for B0 field inhomogeneity and/or one or more tissue parameters along.

In an embodiment, the reconstruction framework 220 may also operate without the Bloch simulator, instead solving an joint optimization problem for the image (as opposed to tissue parameter maps) as well as field inhomogeneity maps represented by the following equation.

$${min}_{f , x} {‖ d - {ℱ}_{Ω} \{ fx \} ‖}_{2}^{2} + {R}_{x} ( x ) + {R}_{f} ( f ) ,$$

where d represents the measurement, F is the Fourier encoding with Ω being the corresponding sampling operator, f is the field map, Rₓ(x) is the regularization on the image (same diffusion prior as described above) and R_{f}(f) is the regularization on the field map (same spatial smoothness constraints as described above). Similarly, this equation may be split into two subproblems and solved by alternating between the two, updating each subproblem with the output of the other, where the image reconstruction (or denoising) subproblem can be effectively solved via the DIFFPIR-based posterior sampling technique (with a pre-learned diffusion prior) through a similar HQS variable splitting step. The diffusion prior ensures the reconstructed image follows the learned data distribution, and the data term narrows down the image manifold with the given measurement. The two new subproblems may be represented similarly by:

$$\begin{matrix}First Subproblem solve for x with fixed f : {min}_{x} {‖ d - {ℱ}_{Ω} \{ fx \} ‖}_{2}^{2} + {R}_{x} ( x ) \\ Second Subproblem solve for f with fixed x : {min}_{f} {‖ d - {ℱ}_{Ω} \{ fx \} ‖}_{2}^{2} + {R}_{f} ( f )\end{matrix}$$

Using the same HQS-based variable splitting strategy, a new auxiliary variable u can be used to decouple the first subproblem. Specifically, with fixed f, we can formulate each step of the new DIFFPRI-like sampling as:

$$\begin{matrix}{x}_{0}^{( t )} = {arg min}_{u} \frac{1}{2 {\overline{σ}}_{t}^{2}} {‖ u - {x}_{t} ‖}^{2} + {𝒫}^{′} ( u ) \\ {\hat{x}}_{0}^{( t )} = {arg min}_{x} {‖ d - {ℱ}_{Ω} \{ fx \} ‖}^{2} + {ρ}_{t} ‖ x - {x}_{0}^{t} ‖ \\ {x}_{t - 1} ← {\hat{x}}_{0}^{( t )} .\end{matrix}$$

Then the field map subproblem can then be written as (with fixed x):

$${min}_{f} {‖ d - {ℱ}_{Ω} \{ fx \} ‖}_{2}^{2} + {R}_{f} ( f ) ,$$

which can then be effectively solved through general gradient descent algorithm.

In an embodiment, the plug-and-play diffusion framework is adapted from or configured as a Denoising Diffusion Probabilistic Model (DDPM) or Deep Diffusion Implicit Model (DDIM). DDPMs are a type of generative model that learn to generate complex data distributions by iteratively refining noisy samples. Diffusion models include a forward diffusion process and a reverse diffusion process. In the forward diffusion process noise is added to an image over multiple time steps, effectively transforming it into a random noise distribution. In the reverse diffusion process, the model denoises the noisy image step by step, effectively recovering (or sampling from) the learned data distribution. In MRI image reconstruction, DDPMs leverage these processes to generate high-fidelity images from undersampled k-space data and/or restore noisy or otherwise deficient images. In embodiments described herein, the DDPM may be used to generate high-fidelity images or tissue parameter maps.

In an embodiment, the plug-and-play diffusion framework uses DDPM for the diffusion model. In an embodiment, in the reverse process, sampling may be adapted from DDIM. DDIM accelerates the sampling process of diffusion models by using non-Markovian diffusion processes. This approach allows for faster generation of high-quality images while maintaining the same training objective as traditional diffusion models. Implicit models focus on representing functions implicitly rather than explicitly. Instead of defining a mathematical formula directly, the implicit model defines a set of equations that describe the relationship between inputs and outputs without specifying the exact function.

The sampling process in DDIM involves sampling from the prior distribution and then iteratively sampling from the conditional distributions. This process is faster than traditional diffusion models because it does not require simulating the entire Markov chain. The number of NFEs, e.g. the total number of times the neural network needs to be called during the sampling process to generate a new image, is typically significantly lower in a DDIM compared to a standard DDPMs due to DDIM's more efficient non-Markovian diffusion process, resulting in faster generation times with fewer computations required. For example, fewer than 50 or 100 NFEs may be required to provide an acceptable output.

In an embodiment, a quadratic sampling technique is used. Sampling involves iteratively refining an image from a noisy initialization by stepping backward through a predefined sequence of time steps. The choice of these steps significantly impacts the efficiency and quality of reconstruction. In a quadratic sampling scheme, the time steps are spaced according to a quadratic function, meaning the interval between successive steps increases quadratically as the sampling process progresses. This contrasts with uniform or geometric schedules, where the time steps are either equally spaced or decrease exponentially. The quadratic approach provides finer resolution in the later stages of denoising, when large noise components must be accurately removed, while allowing larger steps in earlier stages. The use of this approach ensures that the early steps focus more on fine-grained denoising while later steps consolidate the reconstructed image. Different sampling techniques within diffusion models, like DPM-Solver or optimized ODE solvers, may also be used to adjust the required NFE.

Different training mechanisms may be used for the diffusion model, such as reparameterization or score-based generative modeling. In an embodiment, the diffusion model is trained in pixel space for complex-valued MRI data, employing a single diffusion prior from a diverse MR image dataset, enabling a universal framework for various inverse problems and clinical applications.

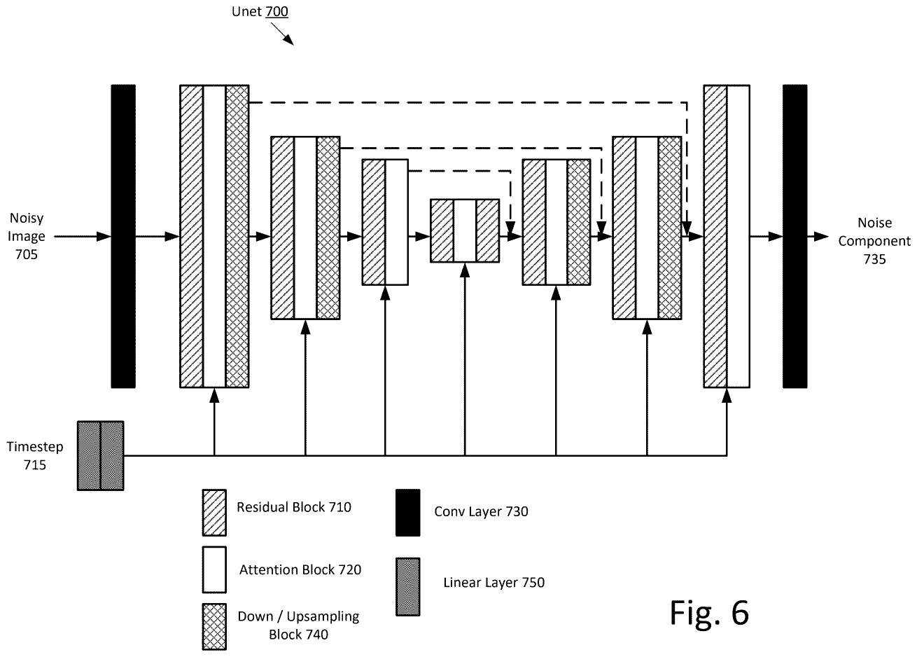

In an embodiment, the diffusion model is fine-tuned using few-shot learning techniques, for example to adapt the prior to the joint tissue parameter tensor. In an embodiment, the diffusion model is based on is a convolutional neural network, in particular, a convolutional neural network having an adapted U-net structure, for example as displayed in FIG. 6. In FIG. 6, the input data to the machine learning network may be a noisy image 705 (or latent representation). The network predicts its noise component 735. In FIG. 6, the u-net architecture includes an encoder path and a decoder path. In the encoder path there are residual blocks (ResBlock) 710, attention blocks 720, and a down sampling operation 740 (max pooling). In the decoder path there are residual blocks 710, attention blocks 720, and up sampling 740. The timestep encodes the current timestep t (for example an integer from 1 to T, where T is the total number of diffusion steps) into a high-dimensional embedding. A linear layer 715 for the timestep is used to transform the timestep embedding. This embedding is then used to condition the U-Net, for example where each ResBlock 710 receives a time embedding. Each ResBlock 710 may be followed by an attention block 720. The attention mechanisms allow the network to apply external conditioning to the network. The modified U-net may be provided or adapted from Project MONAI herein incorporated by reference in its entirety.

At Act A130, the MR reconstruction framework 220, outputs one or more tissue parameter maps (or high-quality images) and/or a field inhomogeneity map. In an embodiment, only the tissue parameter maps (or high-quality images) are output. The computation of the field inhomogeneity map may be pre-measured and used during the process in order to provide more accurate (un-distorted) tissue parameter maps (or reconstructed images). The computation of the field inhomogeneity map is thus a key component of the process but may not be output to a user or, for example, displayed even if it is used during the process to correct distortions in the tissue parameter maps or reconstructed image(s). In an embodiment, if the patient scan generates both raw MR data and pre-measured field inhomogeneity maps, and a user is satisfied with the pre-computed map, the method may still output one or more tissue parameter maps (or high-quality images) only without updating the field inhomogeneity maps.

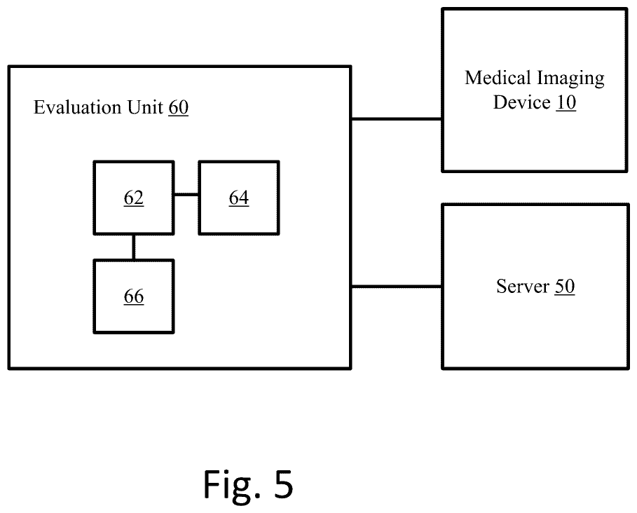

FIG. 5 depicts an example system for Bloch-simulator-based joint reconstruction and field inhomogeneity estimation. The system is configured to perform the method of FIG. 4 and other acts described herein. In FIG. 5, an evaluation unit 60 includes a processor 62, memory 64, and interface 66. In an embodiment, the evaluation unit 60 is configured for Bloch-simulator-based joint reconstruction and field inhomogeneity estimation. The evaluation unit 60 is in communication with a medical imaging device 10, for example as described in FIG. 1, and a server 50. The evaluation unit includes a processor, a memory, and an interface. The medical imaging device is configured to acquire MR imaging data, for example k-space data that is reconstructed into an MR image of an organ or region of a patient 15. The evaluation unit 60 may further be configured to reconstruct an image from the MR data acquired by the medical imaging device 10. The reconstructed image may be a two-dimensional distribution of pixels representing an area of the patient 15 and/or a three-dimensional distribution of voxels representing a volume of the patient 15. The processor is configured to implement diffusion models configured for Bloch-simulator-based joint reconstruction and field inhomogeneity estimation. The diffusion models may input a noisy image and denoise the image. The memory 64 is configured to store instructions and the parameters for the model(s). The interface 66 is configured to display the reconstructed field map, tissue parameters, images, etc. and/or accept inputs from a user. The server 50 may perform similar tasks as the evaluation unit 60 and/or may provide additional processing, storage, or analysis for example using a cloud based platform.

In an embodiment, the medical imaging device 10 is an MR imaging device 10, for example, as described above in FIG. 1. The MR system 10 of FIG. 1 includes an MR scanner or system, a computer based on data obtained by MR scanning, a server, or another processor. The MR imaging device 10 is only exemplary, and a variety of MR scanning systems may be used to collect the MR data. The MR imaging device 10 (also referred to as a MR scanner or image scanner) is configured to scan a patient 15. The MR imaging device 10 scans a patient 15 to provide k-space measurements (measurements in the frequency domain) using a specific protocol. The protocol and k-space measurements are input into a MR simulator 225 that may be stored in the memory 64 and implemented by the processor 62.

The processor may include an image processor that estimates field inhomogeneity using a machine learning network (machine learning model). The image processor is a general processor, digital signal processor, three-dimensional data processor, graphics processing unit, application specific integrated circuit, field programmable gate array, artificial intelligence processor, digital circuit, analog circuit, combinations thereof, or another now known or later developed device for image generation. The image processor is a single device, a plurality of devices, or a network. For more than one device, parallel or sequential division of processing may be used. Different devices making up the image processor may perform different functions. In one embodiment, the image processor is also a control processor or other processor of the imaging device. Other image processors of the imaging device or external to the imaging device may be used. The image processor is configured by software, firmware, and/or hardware to process the data acquired by the imaging device and output one or more images, field inhomogeneity maps, and/or tissue parameter maps, for example using the alternating reconstruction framework 220.

The interface 66 includes an input device and an output device. The input may be an interface, such as interfacing with a computer network, memory, database, medical image storage, or other source of input data. The input may be a user input device, such as a mouse, trackpad, keyboard, roller ball, touch pad, touch screen, or another apparatus for receiving user input. The output is a display device but may be an interface. The field inhomogeneity maps, and/or tissue parameter maps (or reconstructed images) are displayed. In another example, a high resolution image of a region of the patient is displayed. The display is a CRT, LCD, plasma, projector, printer, or other display device. The display is configured by loading an image to a display plane or buffer. The display is configured to display the field inhomogeneity maps, tissue parameter maps, and/or an image(s) of the region of the patient. The interface 66 may include a graphical user interface (GUI) enabling user interaction with the medical imaging device and enables user modification.

The instructions for implementing the processes, methods, and/or techniques discussed herein are provided on non-transitory computer-readable storage media or memories, such as a cache, buffer, RAM, removable media, hard drive, or other computer readable storage media, for example the memory 64. The instructions are executable by the processor or another processor. Computer readable storage media include various types of volatile and nonvolatile storage media. The functions, acts or tasks illustrated in the figures or described herein are executed in response to one or more sets of instructions stored in or on computer readable storage media. The functions, acts or tasks are independent of the instructions set, storage media, processor or processing strategy and may be performed by software, hardware, integrated circuits, firmware, micro code, and the like, operating alone or in combination. In one embodiment, the instructions are stored on a removable media device for reading by local or remote systems. In other embodiments, the instructions are stored in a remote location for transfer through a computer network. In yet other embodiments, the instructions are stored within a given computer, CPU, GPU, or system. Because some of the constituent system components and method steps depicted in the accompanying figures may be implemented in software, the actual connections between the system components (or the process steps) may differ depending upon the manner in which the present embodiments are programmed.

In an embodiment, the processor 62 implements one or more machine learning networks that are stored in the memory in order to provide the MR simulation. In general, a trained machine learning network mimics cognitive functions that humans associate with other human minds. In particular, by training based on training data the machine learning network is able to adapt to new circumstances and to detect and extrapolate patterns. Another term for “trained machine learning network” is “trained function”. In general, parameters of a machine learning network can be adapted by means of training. In particular, supervised training, semi-supervised training, unsupervised training, reinforcement learning and/or active learning can be used. Furthermore, representation learning (an alternative term is “feature learning”) can be used. In particular, the parameters of the machine learning networks can be adapted iteratively by several steps of training. In particular, within the training a certain cost function can be minimized. In particular, within the training of a neural network the backpropagation algorithm can be used. In particular, a machine learning network may comprise a neural network, a support vector machine, a decision tree and/or a Bayesian network, and/or the machine learning network can be based on k-means clustering, Q-learning, genetic algorithms, and/or association rules. In particular, a neural network can be a deep neural network, a convolutional neural network, or a convolutional deep neural network. Furthermore, a neural network can be an adversarial network, a deep adversarial network, a generative network, and/or a generative adversarial network.

In an embodiment, the processor 22 implements a diffusion process for training and configuring the optimization process in the reconstruction framework 220. The diffusion process includes forward diffusion and reverse diffusion. Forward diffusion is used to add noise to the input image using a schedule which determines how much noise is added at the given step t. Reverse diffusion consists of multiple steps in which a small amount of noise is removed at every step. In an embodiment, the diffusion models use a modified U-Net architecture, for example as described above in FIG. 6. In an embodiment, the model(s) are provided by or implemented with a neural network trained using deep learning. The network(s) may be defined as a plurality of sequential feature units or layers. Sequential is used to indicate the general flow of output feature values from one layer to input to a next layer. The information from the next layer is fed to a next layer, and so on until the final output. The layers may only feed forward or may be bi-directional, including some feedback to a previous layer. The nodes of each layer or unit may connect with all or only a sub-set of nodes of a previous and/or subsequent layer or unit. Skip connections may be used, such as a layer outputting to the sequentially next layer as well as other layers. Rather than pre-programming the features and trying to relate the features to attributes, the deep architecture is defined to learn the features at different levels of abstraction the input data. The features are learned to reconstruct lower level features (i.e., features at a more abstract or compressed level). For example, features for generating a fused image or higher resolution image are learned. For a next unit, features for reconstructing the features of the previous unit are learned, providing more abstraction. Each node of the unit represents a feature. Different units are provided for learning different features.

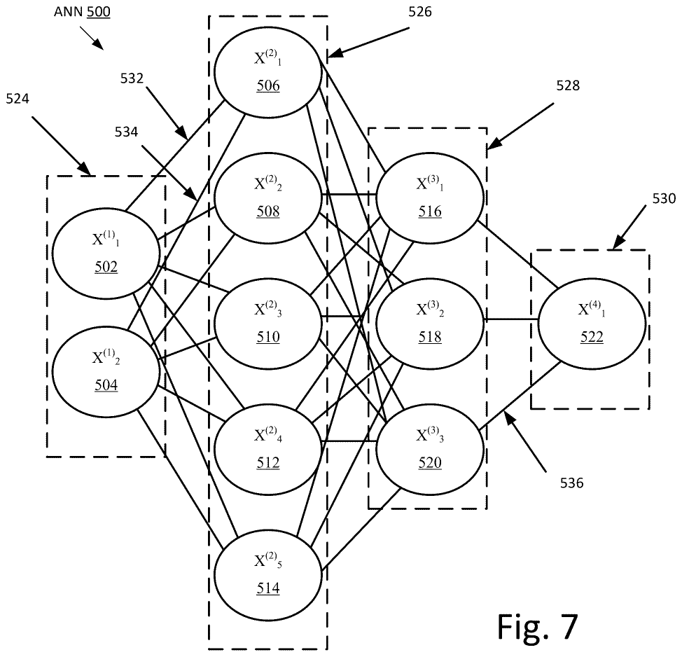

Various units or layers may be used, such as convolutional, pooling (e.g., max-pooling), deconvolutional, fully connected, or other types of layers. Within a unit or layer, any number of nodes is provided. For example, 100 nodes are provided. Later or subsequent units may have more, fewer, or the same number of nodes. In general, for convolution, subsequent units have more abstraction. FIG. 7 shows an embodiment of an artificial neural network (ANN) 500, in accordance with one or more embodiments. Alternative terms for “artificial neural network” are “neural network”, “artificial neural net” or “neural net”. The artificial neural network 500 may be used in part in, for example, the one or more machine learning based networks utilized for the diffusion network(s), etc.

The artificial neural network 500 includes nodes 502-522 and edges 532, 534, . . . , 536, wherein each edge 532, 534, . . . , 536 is a directed connection from a first node 502-522 to a second node 502-522. In general, the first node 502-522 and the second node 502-522 are different nodes 502-522, it is also possible that the first node 502-522 and the second node 502-522 are identical. For example, in FIG. 7, the edge 532 is a directed connection from the node 502 to the node 506, and the edge 534 is a directed connection from the node 504 to the node 506. An edge 532, 534, . . . , 536 from a first node 502-522 to a second node 502-522 is also denoted as “ingoing edge” for the second node 502-522 and as “outgoing edge” for the first node 502-522.

In this embodiment, the nodes 502-522 of the artificial neural network 500 may be arranged in layers 524-530, wherein the layers may include an intrinsic order introduced by the edges 532, 534, . . . , 536 between the nodes 502-522. In particular, edges 532, 534, . . . , 536 may exist only between neighboring layers of nodes. In the embodiment shown in FIG. 7, there is an input layer 524 including only nodes 502 and 504 without an incoming edge, an output layer 530 including only node 522 without outgoing edges, and hidden layers 526, 528 in-between the input layer 524 and the output layer 530. In general, the number of hidden layers 526, 528 may be chosen arbitrarily. The number of nodes 502 and 504 within the input layer 524 usually relates to the number of input values of the neural network 500, and the number of nodes 522 within the output layer 530 usually relates to the number of output values of the neural network 500.

In particular, a (real) number may be assigned as a value to every node 502-522 of the neural network 500. Here, x⁽ⁿ⁾ᵢ denotes the value of the i-th node 502-522 of the n-th layer 524-530. The values of the nodes 502-522 of the input layer 524 are equivalent to the input values of the neural network 500, the value of the node 522 of the output layer 530 is equivalent to the output value of the neural network 500. Furthermore, each edge 532, 534, . . . , 536 may include a weight being a real number, in particular, the weight is a real number within the interval [−1, 1] or within the interval [0, 1]. Here, w^{(m,n)}_{i,j} denotes the weight of the edge between the i-th node 502-522 of the m-th layer 524-530 and the j-th node 502-522 of the n-th layer 524-530. Furthermore, the abbreviation w⁽ⁿ⁾_{i,j} is defined for the weight w^{(n,n+1)}_{i,j}.

In particular, to calculate the output values of the neural network 500, the input values are propagated through the neural network. In particular, the values of the nodes 502-522 of the (n+1)-th layer 524-530 may be calculated based on the values of the nodes 502-522 of the n-th layer 524-530 by

$${x}_{j}^{( n + 1 )} = f ( {\sum }_{i} {x}_{i}^{( n )} \cdot {w}_{i , j}^{( n )} ) .$$

Herein, the function f is a transfer function (another term is “activation function”). Known transfer functions are step functions, sigmoid function (e.g. the logistic function, the generalized logistic function, the hyperbolic tangent, the Arctangent function, the error function, the smoothstep function) or rectifier functions. The transfer function is mainly used for normalization purposes.

In particular, the values are propagated layer-wise through the neural network, wherein values of the input layer 524 are given by the input of the neural network 500, wherein values of the first hidden layer 526 may be calculated based on the values of the input layer 524 of the neural network, wherein values of the second hidden layer 528 may be calculated based in the values of the first hidden layer 526, etc.

In order to set the values w^{(m,n)}_{i,j} for the edges, the neural network 500 has to be trained using training data. In particular, training data includes training input data and training output data (denoted as tᵢ). For a training step, the neural network 500 is applied to the training input data to generate calculated output data. In particular, the training data and the calculated output data include a number of values, said number being equal with the number of nodes of the output layer.

In particular, a comparison between the calculated output data and the training data is used to recursively adapt the weights within the neural network 500 (backpropagation algorithm). In particular, the weights are changed according to

$${w}_{i , j}^{′ ( n )} = {w}_{i , j}^{( n )} - γ \cdot {δ}_{j}^{( n )} \cdot {x}_{i}^{( n )}$$

wherein γ is a learning rate, and the numbers δ⁽ⁿ⁾ⱼ may be recursively calculated as

$${δ}_{j}^{( n )} = ( {\sum }_{k} {δ}_{k}^{( n + 1 )} \cdot {w}_{j , k}^{( n + 1 )} ) \cdot {f}^{′} ( {\sum }_{i} {x}_{i}^{( n )} \cdot {w}_{i , j}^{( n )} )$$

based on δ⁽ⁿ⁺¹⁾ⱼ, if the (n+1)-th layer is not the output layer, and

$${δ}_{j}^{( n )} = ( {x}_{k}^{( n + 1 )} - {t}_{j}^{( n + 1 )} ) \cdot {f}^{′} ( {\sum }_{i} {x}_{i}^{( n )} \cdot {w}_{i , j}^{( n )} )$$

if the (n+1)-th layer is the output layer 530, wherein f′ is the first derivative of the activation function, and y⁽ⁿ⁺¹⁾ⱼ is the comparison training value for the j-th node of the output layer 530.

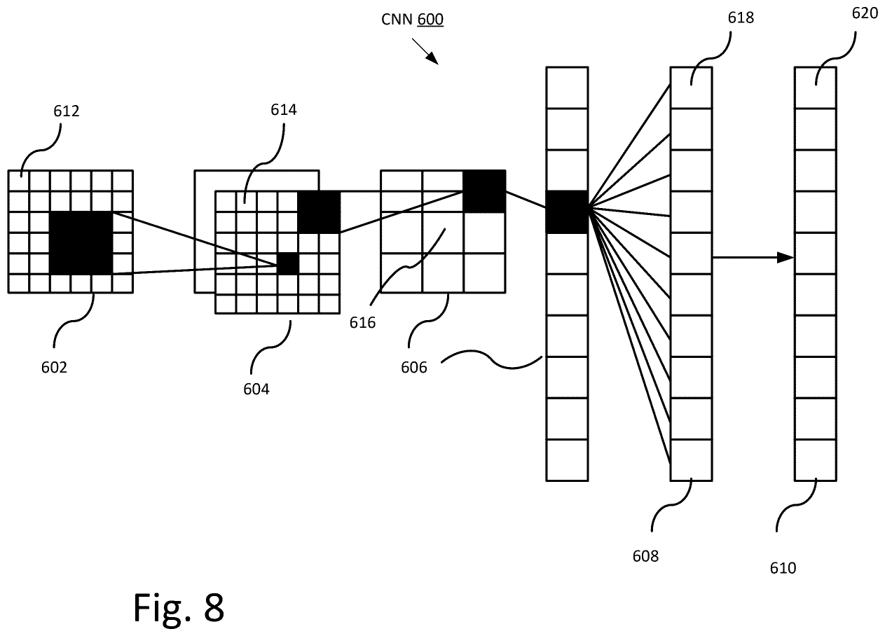

FIG. 8 shows a convolutional neural network (CNN) 600, in accordance with one or more embodiments. Machine learning networks described herein, such as, e.g., the diffusion network(s) etc. may be implemented using convolutional neural network 600.

In the embodiment shown in FIG. 8 the convolutional neural network 600 includes an input layer 602, a convolutional layer 604, a pooling layer 606, a fully connected layer 608, and an output layer 610. Alternatively, the convolutional neural network 600 may include several convolutional layers 604, several pooling layers 606, and several fully connected layers 608, as well as other types of layers. The order of the layers may be chosen arbitrarily, usually fully connected layers 608 are used as the last layers before the output layer 610.

In particular, within a convolutional neural network 600, the nodes 612-620 of one layer 602-610 may be considered to be arranged as a d-dimensional matrix or as a d-dimensional image. In particular, in the two-dimensional case the value of the node 612-620 indexed with i and j in the n-th layer 602-610 may be denoted as x⁽ⁿ⁾_{[i,j]}. However, the arrangement of the nodes 612-620 of one layer 602-610 does not have an effect on the calculations executed within the convolutional neural network 600 as such, since these are given solely by the structure and the weights of the edges.

In particular, a convolutional layer 604 is characterized by the structure and the weights of the incoming edges forming a convolution operation based on a certain number of kernels. In particular, the structure and the weights of the incoming edges are chosen such that the values x⁽ⁿ⁾ₖ of the nodes 614 of the convolutional layer 604 are calculated as a convolution x⁽ⁿ⁾ₖ=Kₖ*x⁽ⁿ⁻¹⁾ based on the values x⁽ⁿ⁻¹⁾ of the nodes 612 of the preceding layer 602, where the convolution * is defined in the two-dimensional case as:

$${x}_{k}^{( n )} [ i , j ] = ( {K}_{k} * {x}^{( n - 1 )} ) [ i , j ] = {\sum }_{{i}^{′}} {\sum }_{{j}^{′}} {K}_{k} [ {i}^{′} , {j}^{′} ] \cdot {x}^{( n - 1 )} [ i - {i}^{′} , j - {j}^{′} ] .$$

Here the k-th kernel Kₖ is a d-dimensional matrix (in this embodiment a two-dimensional matrix), which is usually small compared to the number of nodes 612-618 (e.g. a 3×3 matrix, or a 5×5 matrix). In particular, this implies that the weights of the incoming edges are not independent, but chosen such that they produce said convolution equation. In particular, for a kernel being a 3×3 matrix, there are only 9 independent weights (each entry of the kernel matrix corresponding to one independent weight), irrespectively of the number of nodes 612-620 in the respective layer 602-610. In particular, for a convolutional layer 604, the number of nodes 614 in the convolutional layer is equivalent to the number of nodes 612 in the preceding layer 602 multiplied with the number of kernels.

If the nodes 612 of the preceding layer 602 are arranged as a d-dimensional matrix, using a plurality of kernels may be interpreted as adding a further dimension (denoted as “depth” dimension), so that the nodes 614 of the convolutional layer 604 are arranged as a (d+1)-dimensional matrix. If the nodes 612 of the preceding layer 602 are already arranged as a (d+1)-dimensional matrix including a depth dimension, using a plurality of kernels may be interpreted as expanding along the depth dimension, so that the nodes 614 of the convolutional layer 604 are arranged also as a (d+1)-dimensional matrix, wherein the size of the (d+1)-dimensional matrix with respect to the depth dimension is by a factor of the number of kernels larger than in the preceding layer 602.

The advantage of using convolutional layers 604 is that spatially local correlation of the input data may exploited by enforcing a local connectivity pattern between nodes of adjacent layers, in particular by each node being connected to only a small region of the nodes of the preceding layer.

In the embodiment shown in FIG. 8, the input layer 602 includes 36 nodes 612, arranged as a two-dimensional 6×6 matrix. The convolutional layer 604 includes 72 nodes 614, arranged as two two-dimensional 6×6 matrices, each of the two matrices being the result of a convolution of the values of the input layer with a kernel. Equivalently, the nodes 614 of the convolutional layer 604 may be interpreted as arranged as a three-dimensional 6×6×2 matrix, wherein the last dimension is the depth dimension.

A pooling layer 606 may be characterized by the structure and the weights of the incoming edges and the activation function of its nodes 616 forming a pooling operation based on a non-linear pooling function f. For example, in the two dimensional case the values x⁽ⁿ⁾ of the nodes 616 of the pooling layer 606 may be calculated based on the values x⁽ⁿ⁻¹⁾ of the nodes 614 of the preceding layer 604 as

$${x}^{( n )} [ i , j ] = f ( {x}^{( n - 1 )} [ {id}_{1} , {jd}_{2} ] , … , {x}^{( n - 1 )} [ i {d}_{1} + {d}_{1} - 1 , j {d}_{2} + {d}_{2} - 1 ] )$$

In other words, by using a pooling layer 606, the number of nodes 614, 616 may be reduced, by replacing a number d1·d2 of neighboring nodes 614 in the preceding layer 604 with a single node 616 being calculated as a function of the values of said number of neighboring nodes in the pooling layer. In particular, the pooling function f may be the max-function, the average, or the L2-Norm. In particular, for a pooling layer 606 the weights of the incoming edges are fixed and are not modified by training.

The advantage of using a pooling layer 606 is that the number of nodes 614, 616 and the number of parameters is reduced. This leads to the amount of computation in the network being reduced and to a control of overfitting.

In the embodiment shown in FIG. 8, the pooling layer 606 is a max-pooling, replacing four neighboring nodes with only one node, the value being the maximum of the values of the four neighboring nodes. The max-pooling is applied to each d-dimensional matrix of the previous layer; in this embodiment, the max-pooling is applied to each of the two two-dimensional matrices, reducing the number of nodes from 72 to 9.

A fully-connected layer 608 may be characterized by the fact that a majority, in particular, all edges between nodes 616 of the previous layer 606 and the nodes 618 of the fully-connected layer 608 are present, and wherein the weight of each of the edges may be adjusted individually.

In this embodiment, the nodes 616 of the preceding layer 606 of the fully-connected layer 608 are displayed both as two-dimensional matrices, and additionally as non-related nodes (indicated as a line of nodes, wherein the number of nodes was reduced for a better presentability). In this embodiment, the number of nodes 618 in the fully connected layer 608 is equal to the number of nodes 616 in the preceding layer 606. Alternatively, the number of nodes 616, 618 may differ.

A convolutional neural network 600 may also include a ReLU (rectified linear units) layer or activation layers with non-linear transfer functions. In particular, the number of nodes and the structure of the nodes contained in a ReLU layer is equivalent to the number of nodes and the structure of the nodes contained in the preceding layer. In particular, the value of each node in the ReLU layer is calculated by applying a rectifying function to the value of the corresponding node of the preceding layer.

The input and output of different convolutional neural network blocks may be wired using summation (residual/dense neural networks), element-wise multiplication (attention) or other differentiable operators. Therefore, the convolutional neural network architecture may be nested rather than being sequential if the whole pipeline is differentiable.

In particular, convolutional neural networks 600 may be trained based on the backpropagation algorithm. For preventing overfitting, methods of regularization may be used, e.g. dropout of nodes 612-620, stochastic pooling, use of artificial data, weight decay based on the L1 or the L2 norm, or max norm constraints. Different loss functions may be combined for training the same neural network to reflect the joint training objectives. A subset of the neural network parameters may be excluded from optimization to retain the weights pretrained on another datasets.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

The following is a list of non-limiting illustrative embodiments disclosed herein:

Illustrative embodiment 1: for Bloch-simulator-based joint reconstruction and field inhomogeneity estimation, the method comprising: performing a patient scan using a MR protocol, the patient scan generating raw MR data; inputting the raw MR data and the MR protocol into a MR simulator configured to implement a joint reconstruction framework, wherein the joint reconstruction framework alternates optimizations of a field inhomogeneity map and tissue parameters using a plug-and-play diffusion framework; and outputting, by the joint reconstruction framework, one or more tissue parameter maps (or reconstructed images) and/or field inhomogeneity maps.

Illustrative embodiment 2. The method of illustrative embodiment 1, wherein the joint reconstruction framework solves a joint minimization problem over the one or more tissue parameter maps and the field inhomogeneity map using:

$${min}_{f , {\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) + {R}_{f} ( f ) ,$$

where d_{c} is a k-space measurement for a c-th coil, Sim{·} represent the MR simulator with input including: Φ sequence parameters retrieved from a measurement protocol, s_{c} representing a coil sensitivity for a c-th coil,

$${\{ {P}_{i} \}}_{i = 0}^{l}$$

representing the one or more tissue parameter maps with in-total l components, and f representing the field inhomogeneity map.

Illustrative embodiment 3. The method of illustrative embodiment 1, wherein solving the joint reconstruction framework comprises solving a joint minimization problem comprising: updating, in a first step, the field inhomogeneity map using a current estimate of tissue parameters (or reconstructed images) by solving a first optimization subproblem; and updating, in a second step, an estimate of tissue parameters using the updated field inhomogeneity map by solving a second optimization subproblem; wherein the first step and second step alternate iteratively until convergence resulting in a joint estimate of the one or more tissue parameter maps (or reconstructed images) and the field inhomogeneity map.

Illustrative embodiment 4. The method of illustrative embodiment 3, wherein the first optimization subproblem comprises:

$${min}_{{\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) ,$$

where d_{c} is a k-space measurement for a c-th coil, Sim{·} represent the MR simulator with input including: Φ sequence parameters retrieved from a measurement protocol, s_{c} representing a coil sensitivity for a c-th coil,

$${\{ {P}_{i} \}}_{i = 0}^{l}$$

representing the one or more tissue parameter maps with in-total l components, and f representing the field inhomogeneity map, wherein

$${R}_{P} ( {\{ {P}_{i} \}}_{i = 0}^{l} )$$

provides regularization.

Illustrative embodiment 5. The method of illustrative embodiment 3, wherein the second optimization subproblem comprises:

$${min}_{f} {‖ {d}_{c} - S i m \{ Φ , {s}_{c} , {\{ {P}_{i} \}}_{i = 0}^{l} , f \} ‖}_{F} + {R}_{f} ( f ) ,$$

where d_{c} is a k-space measurement for a c-th coil, Sim{·} represent the MR simulator with input including: Φ sequence parameters retrieved from a measurement protocol, s_{c} representing a coil sensitivity for a c-th coil,

$${\{ {P}_{i} \}}_{i = 0}^{l}$$

representing the one or more tissue parameter maps with in-total l components, and f representing the field inhomogeneity map, wherein R_{f}(f) provides regularization.

Illustrative embodiment 6. The method of illustrative embodiment 1, wherein the plug-and-play diffusion framework comprises: a denoising diffusion implicit model.

Illustrative embodiment 7. The method of illustrative embodiment 6, wherein the denoising diffusion implicit model is fine-tuned using a few-shot or a one-shot training strategy.

Illustrative embodiment 8. The method of illustrative embodiment 1, further comprising: performing a system-wise calibration scan to determine system-dependent field perturbations, wherein the system-dependent field perturbations are input into the MR simulator.

Illustrative embodiment 9. The method of illustrative embodiment 1, further comprising outputting one or more field inhomogeneity maps estimated by the joint reconstruction framework.

Illustrative embodiment 10. A system for Bloch-simulator-based joint reconstruction and field inhomogeneity estimation, the system comprising: an magnetic resonance (MR) scanner configured to scan a patient using a MR protocol, the scan generating MR data; and a MR simulator, the MR simulator configured to implement a joint reconstruction framework, wherein the joint reconstruction framework alternates optimizations of a field inhomogeneity map and tissue parameters (or reconstructed images) using a plug-and-play diffusion framework to output, when input the MR data and MR protocol, one or more high quality tissue parameter maps (or images) and/or field inhomogeneity maps.

Illustrative embodiment 11. The system of illustrative embodiment 10, wherein the joint reconstruction framework is further configured to output the field inhomogeneity map.

Illustrative embodiment 12. The system of illustrative embodiment 10, wherein the joint reconstruction framework solves a joint minimization problem over the one or more tissue parameter maps and the field inhomogeneity map using:

$${min}_{f , {\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) + {R}_{f} ( f ) ,$$

where d_{c} is a k-space measurement for a c-th coil, Sim{·} represent the MR simulator with input including: Φ sequence parameters retrieved from a measurement protocol, s_{c} representing a coil sensitivity for a c-th coil,

$${\{ {P}_{i} \}}_{i = 0}^{l}$$

representing the one or more tissue parameter maps with in-total l components, and f representing the field inhomogeneity map.

Illustrative embodiment 13. The system of illustrative embodiment 12, wherein solving the joint minimization problem comprises: updating, in a first step, the field inhomogeneity map using a current estimate of tissue parameters by solving a first optimization subproblem; and updating, in a second step, an estimate of tissue parameters using the updated field inhomogeneity map by solving a second optimization subproblem; wherein the first step and second step alternate iteratively until convergence resulting in a joint estimate of the one or more tissue parameter maps and the field inhomogeneity map.

Illustrative embodiment 14. The system of illustrative embodiment 13, wherein the first optimization subproblem comprises:

$${min}_{f , {\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) ,$$

where d_{c} is a k-space measurement for a c-th coil, Sim{·} represent the MR simulator with input including: Φ sequence parameters retrieved from a measurement protocol, s_{c} representing a coil sensitivity for a c-th coil,

$${\{ {P}_{i} \}}_{i = 0}^{l}$$

representing the one or more tissue parameter maps with in-total l component, and f representing the field inhomogeneity map, wherein

$${R}_{P} ( {\{ {P}_{i} \}}_{i = 0}^{l} )$$

provides regularization.

Illustrative embodiment 15. The system of illustrative embodiment 13, wherein the second optimization subproblem comprises:

$${min}_{f} {‖ {d}_{c} - S i m \{ Φ , {s}_{c} , {\{ {P}_{i} \}}_{i = 0}^{l} , f \} ‖}_{F} + {R}_{f} ( f ) ,$$

where d_{c} is a k-space measurement for a c-th coil, Sim{·} represent the MR simulator with input including: Φ sequence parameters retrieved from a measurement protocol, s_{c} representing a coil sensitivity for a c-th coil,

$${\{ {P}_{i} \}}_{i = 0}^{l}$$

representing the one or more tissue parameter maps with in-total l component, and f representing the field inhomogeneity map, wherein R_{f}(f) provides regularization.

Illustrative embodiment 16. The system of illustrative embodiment 10, wherein the plug-and-play diffusion framework comprises: a denoising diffusion implicit model.

Illustrative embodiment 17. The system of illustrative embodiment 16, wherein the denoising diffusion implicit model is fine-tuned using a few shot or a one shot training strategy.

Illustrative embodiment 18. The system of illustrative embodiment 10, wherein the MR scanner is further configured to perform a system-wise calibration scan to determine system-dependent field perturbations, wherein the system-dependent field perturbations are input into the MR simulator.

Illustrative embodiment 19. The system of illustrative embodiment 10, wherein the MR simulator comprises a fully differentiable Bloch simulator.

Illustrative embodiment 20. A non-transitory computer implemented storage medium, including machine-readable instructions stored therein for Bloch-simulator-based joint reconstruction and field inhomogeneity estimation, the instructions when executed by at least one processor, cause the processor to: acquire MR data of a patient acquired in an imaging procedure using a MR protocol; input the MR data and the MR protocol into a MR simulator configured to compute tissue parameters and the field inhomogeneity using a joint reconstruction framework, wherein the joint reconstruction framework alternates optimizations of a field inhomogeneity map and tissue parameters using a plug-and-play diffusion framework; and output one or more tissue parameter maps and the field inhomogeneity map for the imaging procedure.

1. A method for Bloch-simulator-based joint reconstruction and field inhomogeneity estimation, the method comprising:
performing a patient scan using a MR protocol, the patient scan generating raw MR data;
inputting the raw MR data and the MR protocol into a MR simulator configured to implement a joint reconstruction framework, wherein the joint reconstruction framework alternates optimizations of a field inhomogeneity map and tissue parameters using a plug-and-play diffusion framework; and
outputting, by the joint reconstruction framework, one or more tissue parameter maps.

2. The method of claim 1, wherein the joint reconstruction framework solves a joint minimization problem over the one or more tissue parameter maps and the field inhomogeneity map using:
$${min}_{f , {\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) + {R}_{f} ( f ) ,$$
where d_{c} is a k-space measurement for a c-th coil, Sim{·} represent the MR simulator with input including: Φ sequence parameters retrieved from a measurement protocol, s_{c} representing a coil sensitivity for a c-th coil,
$${\{ {P}_{i} \}}_{i = 0}^{l}$$
representing the one or more tissue parameter maps with in-total l components, and f representing the field inhomogeneity map.

3. The method of claim 1, wherein solving the joint reconstruction framework comprises solving a joint minimization problem comprising:
updating, in a first step, the field inhomogeneity map using a current estimate of tissue parameters by solving a first optimization subproblem; and
updating, in a second step, an estimate of tissue parameters using the updated field inhomogeneity map by solving a second optimization subproblem;
wherein the first step and second step alternate iteratively until convergence resulting in a joint estimate of the one or more tissue parameter maps and the field inhomogeneity map.

4. The method of claim 3, wherein the first optimization subproblem comprises:
$${min}_{{\{ {P}_{i} \}}_{i = 0}^{l}} {‖ {d}_{C} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) ,$$
where d_{c} is a k-space measurement for a c-th coil, Sim{·} represent the MR simulator with input including: Φ sequence parameters retrieved from a measurement protocol, s_{c} representing a coil sensitivity for a c-th coil,
$${\{ {P}_{i} \}}_{i = 0}^{l}$$
representing the one or more tissue parameter maps with in-total l components, and f representing the field inhomogeneity map, wherein
$${R}_{P} ( {\{ {P}_{i} \}}_{i = 0}^{l} )$$
provides regularization.

5. The method of claim 3, wherein the second optimization subproblem comprises:
$${min}_{f} {‖ {d}_{c} - Sim \{ Φ , {s}_{c} , {\{ {P}_{i} \}}_{i = 0}^{l} , f \} ‖}_{F} + {R}_{f} ( f ) ,$$
where d_{c} is a k-space measurement for a c-th coil, Sim{·} represent the MR simulator with input including: Φ sequence parameters retrieved from a measurement protocol, s_{c} representing a coil sensitivity for a c-th coil,
$${\{ {P}_{i} \}}_{i = 0}^{l}$$
representing the one or more tissue parameter maps with in-total l components, and f representing the field inhomogeneity map, wherein R_{f}(f) provides regularization.

6. The method of claim 1, wherein the plug-and-play diffusion framework comprises: a denoising diffusion implicit model.

7. The method of claim 6, wherein the denoising diffusion implicit model is fine-tuned using a few shot or a one-shot training strategy.

8. The method of claim 1, further comprising:
performing a system-wise calibration scan to determine system-dependent field perturbations, wherein the system-dependent field perturbations are input into the MR simulator.

9. The method of claim 1, further comprising:
outputting one or more field inhomogeneity maps estimated by the joint reconstruction framework.

10. A system for Bloch-simulator-based joint reconstruction and field inhomogeneity estimation, the system comprising:
an magnetic resonance (MR) scanner configured to scan a patient using a MR protocol, the scan generating MR data; and
a MR simulator, the MR simulator configured to implement a joint reconstruction framework, wherein the joint reconstruction framework alternates optimizations of a field inhomogeneity map and tissue parameters using a plug-and-play diffusion framework, the MR simulator configured to output, when input the MR data and MR protocol, one or more tissue parameter maps.

11. The system of claim 10, wherein the joint reconstruction framework is further configured to output the field inhomogeneity map.

12. The system of claim 10, wherein the joint reconstruction framework solves a joint minimization problem over the one or more tissue parameter maps and the field inhomogeneity map using:
$${min}_{f , {\{ {P}_{i} \}}_{i = 0}^{l}} {‖ {d}_{c} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) + {R}_{f} ( f ) ,$$
where d_{c} is a k-space measurement for a c-th coil, Sim{·} represent the MR simulator with input including: Φ sequence parameters retrieved from a measurement protocol, s_{c} representing a coil sensitivity for a c-th coil,
$${\{ {P}_{i} \}}_{i = 0}^{l}$$
representing the one or more tissue parameter maps with in-total l components, and f representing the field inhomogeneity map.

13. The system of claim 12, wherein solving the joint minimization problem comprises:
updating, in a first step, the field inhomogeneity map using a current estimate of tissue parameters by solving a first optimization subproblem; and
updating, in a second step, an estimate of tissue parameters using the updated field inhomogeneity map by solving a second optimization subproblem;
wherein the first step and second step alternate iteratively until convergence resulting in a joint estimate of the one or more tissue parameter maps and the field inhomogeneity map.

14. The system of claim 13, wherein the first optimization subproblem comprises:
$${min}_{{\{ {P}_{i} \}}_{i = 0}^{l}} {‖ {d}_{C} - Sim \{ Φ , {s}_{c} , {\{ {P}_{i} \}}_{i = 0}^{l} , f \} ‖}_{F} + {R}_{P} ( {\{ {P}_{i} \}}_{i = 0}^{l} ) ,$$
where d_{c} is a k-space measurement for a c-th coil, Sim{ } represent the MR simulator with input including: Φ sequence parameters retrieved from a measurement protocol, s_{c} representing a coil sensitivity for a c-th coil,
$${\{ {P}_{i} \}}_{i = 0}^{l}$$
representing the one or more tissue parameter maps with in-total l component, and f representing the field inhomogeneity map, wherein
$${R}_{P} ( {\{ {P}_{i} \}}_{i = 0}^{l} )$$
provides regularization.

15. The system of claim 13, wherein the second optimization subproblem comprises:
$${min}_{f} {‖ {d}_{c} - Sim \{ Φ , {s}_{c} , {\{ {P}_{i} \}}_{i = 0}^{l} , f \} ‖}_{F} + {R}_{f} ( f ) ,$$
where d_{c} is a k-space measurement for a c-th coil, Sim{ } represent the MR simulator with input including: Φ sequence parameters retrieved from a measurement protocol, s_{c} representing a coil sensitivity for a c-th coil,
$${\{ {P}_{i} \}}_{i = 0}^{l}$$
representing the one or more tissue parameter maps with in-total l component, and f representing the field inhomogeneity map, wherein R_{f}(f) provides regularization.

16. The system of claim 10, wherein the plug-and-play diffusion framework comprises: a denoising diffusion implicit model.

17. The system of claim 16, wherein the denoising diffusion implicit model is fine-tuned using a few shot or a one shot training strategy.

18. The system of claim 10, wherein the MR scanner is further configured to perform a system-wise calibration scan to determine system-dependent field perturbations, wherein the system-dependent field perturbations are input into the MR simulator.

19. The system of claim 10, wherein the MR simulator comprises a fully differentiable Bloch simulator.

20. A non-transitory computer implemented storage medium, including machine-readable instructions stored therein for Bloch-simulator-based joint reconstruction and field inhomogeneity estimation, the instructions when executed by at least one processor, cause the processor to:
acquire MR data of a patient acquired in an imaging procedure using a MR protocol;
input the MR data and the MR protocol into a MR simulator configured to compute tissue parameters and the field inhomogeneity using a joint reconstruction framework, wherein the joint reconstruction framework alternates optimizations of a field inhomogeneity map and tissue parameters using a plug-and-play diffusion framework; and
output one or more tissue parameter maps and a field inhomogeneity map for the imaging procedure.
